(19) United States
(12) Patent Application Publication
(10) Pub. No.: US 2020/0025965 A1
(43) Pub. Date: Jan. 23, 2020

(54) MAGNET POSITION DETECTION IN A MAGNETIC CONNECTOR

(71) Applicant: NANOPORT TECHNOLOGY INC., Markham, ON (CA)

(72) Inventor: Timothy Jing Yin SZETO, Markham (CA)

(21) Appl. No.: 16/071,260

(22) PCT Filed: Jan. 18, 2017
(86) PCT No.: PCT/CA2017/050055

§ 371 Date: Jul. 19, 2018

Related U.S. Application Data
(60) Provisional application No. 62/280,329, filed on Jan. 19, 2016.
(60) Provisional application No. 62/327,826, filed on Apr. 26, 2016.

(51) Int. Cl. G01V 3/08; H05K 7/16; G01R 33/07

(52) U.S. Cl. CPC G01V 3/081; G01R 33/072; H05K 7/16

(57) ABSTRACT

A device is magnetically interconnectable to another device by way of a magnetic connector. Within a cavity of the magnetic connector, a magnet is movable between a first and second position. An external magnet in the other device may urge the magnet into the first position in the cavity. A magnetic stop within the device magnetically attracts the magnet towards the second position in the cavity. A sensor detects the magnet in one of the first position and second position. The position of the magnet may be used to determine whether devices are connected or disconnected from each other.

### CROSS-REFERENCE TO RELATED APPLICATIONS

This application claims priority from U.S. Provisional Patent Application No. 62/280,329 filed Jan. 19, 2016, and U.S. Provisional Patent Application No. 62/327,826 filed Apr. 26, 2016, the entire contents of which are hereby incorporated by reference herein.

### TECHNICAL FIELD

This relates to magnetic connectors for connecting devices to one another, and in particular, detecting a position of magnets within magnetic connectors in a device to determine whether devices are connected or disconnected from each other.

### BACKGROUND

Many electronic devices, including mobile electronic devices (e.g., smartphones, tablet computers, laptop computers) have the ability to connect with a variety of other devices (e.g., peripherals—in the form of display screens, touch screens, keyboards, batteries, speakers, sensors, cameras, communication devices) that come in various form factors and sizes. Peripheral devices may connect mechanically and/or electrically with the electronic device in various configurations and positions.

The connection between peripheral devices and electronic devices may be achieved by way of magnetic connectors in each device such that when the devices are placed proximate each other, the magnetic connectors engage with one another, establishing a mechanical connection between the devices. An electrical connection may also be established through engagement of the magnetic connectors.

By using an electrical connection established between devices through the magnetic connectors, a connection or disconnection between the magnetic connectors may be detected through changes in electrical properties (e.g., impedance, voltage) at the magnetic connectors.

If a data connection is established between devices through the magnetic connectors, a connection or disconnection between the magnetic connectors may be detected through the presence or absence of data signals (e.g., handshaking signals, timeouts).

The above detection methods, however, may be expensive and/or slow, and require the establishment of an electrical connection or a data connection.

Accordingly, there is a need for an improved detection of connection or disconnection states of a magnetic connector.

### SUMMARY

According to an aspect, there is provided a device that is magnetically interconnectable to another device. The device includes a body defining a cavity and a magnet received within the cavity that is movable between a first position and a second position in the cavity. The magnet is magnetically interconnectable with an external magnet in the other device that urges the magnet into the first position. The device also includes a magnetic stop that magnetically attracts the magnet toward the second position in the cavity. Further, the device further includes a sensor to detect the magnet in one of the first position and the second position.

According to another aspect, there is provided a method of detecting a position of a magnet in a device that is magnetically interconnectable to another device. The method includes biasing the magnet, that is received within a cavity defined by a body and is magnetically interconnectable with an external magnet in the other device in a first position in the cavity, into a second position in the cavity, and detecting the magnet in one of the first position and the second position.

Other features will become apparent from the drawings in conjunction with the following description.

### BRIEF DESCRIPTION OF THE DRAWINGS

In the figures which illustrate example embodiments,

FIG. 1 is a perspective view of two electronic devices arranged side by side and containing magnetic connectors, exemplary of an embodiment;

FIG. 2 is a partial cross-sectional view of two connected magnetic connectors of the two electronic devices of FIG. 1, illustrating internal components of each magnetic connector;

FIG. 3 is a partial cross-sectional view of two disconnected magnetic connectors of the two electronic devices of FIG. 1;

FIG. 4A is a partial cross-section view of a magnetic connector connected to another magnetic connector (not shown), and a detection circuit, exemplary of an embodiment;

FIG. 4B is a partial cross-section view of the magnetic connector and detection circuit of FIG. 4A, the magnetic connector disconnected from another magnetic connector (not shown);

FIG. 5A is a partial cross-section view of a magnetic connector connected to another magnetic connector (not shown) and a detection circuit, exemplary of an embodiment;

FIG. 5B is a partial cross-section view of the magnetic connector and detection circuit of FIG. 5A, the magnetic connector disconnected from another magnetic connector (not shown);

FIG. 6A is a partial cross-section view of a magnetic connector connected to another magnetic connector (not shown) and a force sensor, exemplary of an embodiment;

FIG. 6B is a partial cross-section view of the magnetic connector and force sensor of FIG. 6A, the magnetic connector disconnected from another magnetic connector (not shown);

FIG. 7A is a partial cross-section view of a magnetic connector connected to another magnetic connector (not shown) and a Hall-effect sensor, exemplary of an embodiment;

FIG. 7B is a partial cross-section view of the magnetic connector and Hall-effect sensor of FIG. 7A, the magnetic connector disconnected from another magnetic connector (not shown);

FIG. 8A is a partial cross-section view of a magnetic connector and a piezoelectric transducer connected to another magnetic connector and another piezoelectric transducer, exemplary of an embodiment;

FIG. 8B is a partial cross-section view of the magnetic connectors and piezoelectric transducers of FIG. 8A, the magnetic connector disconnected;

FIG. 9 is a perspective view of two electronic devices, containing magnetic connectors, in a configuration, exemplary of an embodiment;

FIG. 10 is a partial cross-section view of two connected magnetic connectors of the two electronic devices of FIG. 9;

FIG. 11 is a perspective view of the two electronic devices of FIG. 9 in an alternate configuration;

FIG. 12 is a partial cross-section view of two connected magnetic connectors of the two electronic devices of FIG. 11; and

FIG. 13 is a front cross-sectional view of a magnetic connector in an electronic device, exemplary of an embodiment.

### DETAILED DESCRIPTION

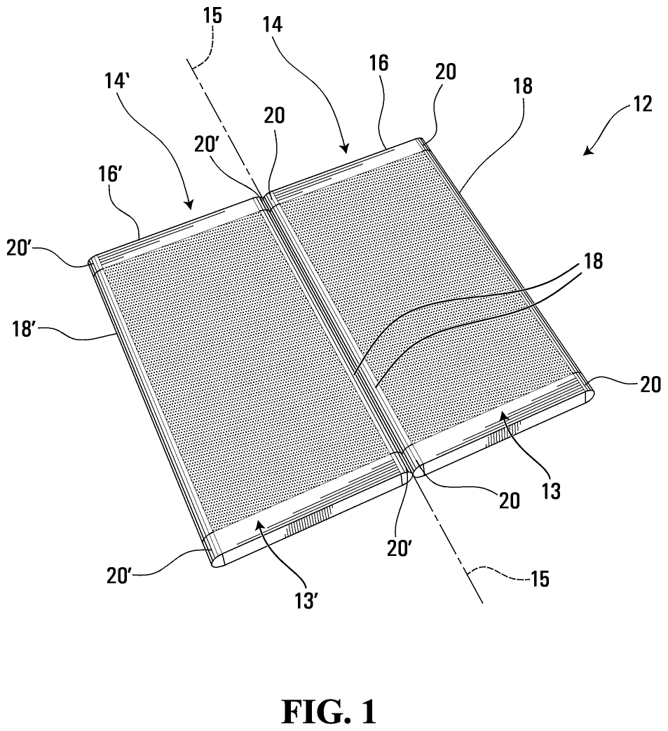

FIG. 1 is a perspective view of two electronic devices 14 and 14′ arranged side by side and containing magnetic connectors 20 and 20′, exemplary of an embodiment. Together, devices 14 and 14′ comprise a device system 12.

Devices 14 and 14′ may be any electronic devices that interface with one another and provide complementary functions. As depicted in FIG. 1, electronic devices 14 and 14′ are smartphones. In other embodiments, one of devices 14 and 14′ may be smartphone and the other an accessory, such as a speaker. As further examples, one of devices 14 and 14′ may be a smartphone and the other a viewing screen, or both may be viewing screens, or one may be a screen and the other a keyboard; one of devices 14 and 14′ may be a touchscreen enabled device and the other a router to communicate to the Internet, or one may be a camera and the other a smart phone to store images from the camera. These examples are non-limiting and it will be apparent that many mutually complementary devices exist that benefit from interconnection and interoperation.

As shown in FIG. 1, device 14 includes a housing 13 defined by contiguous external surface 16 and lateral edges 18. Device 14 also includes magnetic connectors 20 at each corner of housing 13.

An example of possible magnetic connector 20 is described in international patent application publication no. WO 2015/070321 and U.S. Pat. No. 9,312,633, the contents of which are hereby incorporated by reference in their entirety. Each connector 20 offers a mechanical coupling function and, optionally, an electrical connection function. A Universal Serial Bus (USB) may be established through the electrical connection. Optionally, devices 14 and 14′ may communicate wirelessly, in which case connectors 20 need not establish an electrical connection.

Device 14′ is generally identical to device 14, including the structure of components including connectors 20′, housing 13′ defined by contiguous external surface 16′, and lateral edges 18′ being the same as connectors 20, housing 13 defined by contiguous external surface 16, and lateral edges 18.

Devices 14 and 14′ may be used together, as shown in FIG. 1. For example, device 14 may be arranged side by side with device 14′ with surfaces 16 and 16′ abutting and connectors 20 and 20′ engaged with one another. Devices 14 and 14′ may be used in such a configuration, for example, to cooperatively render or display content using displays of both devices 14 and 14′.

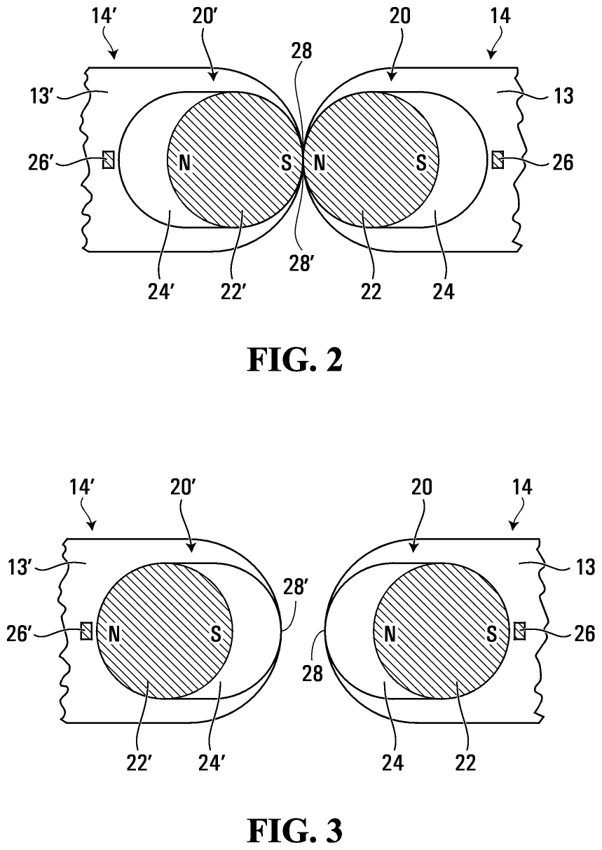

FIG. 2 is a partial cross-sectional view of a magnetic connector 20 of device 14 connected to a magnetic connector 20′ of device 14′, of FIG. 1, illustrating internal components of magnetic connectors 20 and 20′.

Magnetic connector 20 contains one or more magnet 22 within a cavity 24 defined by housing 13. Magnet 22 may be generally cylindrical or spherical, in which case device 14 may pivot relative to device 14′ about axis 15 (see e.g., FIG. 1). Magnet 22 may be diametrically-magnetized such that one semicylinder is a north pole (shown as N in FIG. 2) and the other semicylinder is a south pole (shown as S in FIG. 2). In some embodiments, magnets 22 may be axially-magnetized such that one planar surface is a north pole and the other planar surface is a south pole. Other magnetized arrangements will be apparent to a person skilled in the art.

Magnet 22 may be formed of a permanent magnet, for example, a ferromagnetic material that has been magnetized such that the applied magnetic field persists as a permanent magnet after removal of an applied magnetic field. Permanent magnets may be made of a suitable rare earth magnet, for example, Neodymium-Iron-Boron, or Samarium-cobalt, or a permanent magnet made of iron, nickel, or other suitable alloy.

Magnet 22 may move within cavity 24. Magnet 22 may, for example, slide or roll away from lateral edge 18. In some embodiments, cavity 24 may be a rounded rectangle in cross-section, as shown, for example, in FIG. 2.

As noted above, magnetic connectors 20′ of device 14′ are generally identical in structure and components to connectors 20 of device 14, including magnets 22 and 22′, and cavities 24 and 24′. In an alternative embodiment, magnet 22′ of connector 20′ may be replaced by a similarly shaped ferromagnetic element that becomes magnetized in the presence of magnet 22.

FIG. 3 is a partial cross-sectional view of a magnetic connector 20 of device 14 disconnected from a magnetic connector 20′ of device 14′, of FIG. 1. If magnetic connector 20 is disconnected from magnetic connector 20′, in magnetic connector 20, magnet 22 is drawn to the rear of cavity 24 (away from a connection surface 28) by attraction of magnet 22 to a magnetic stop located towards the rear of the cavity, illustrated in FIGS. 2 and 3 as ferrous stop 26.

Ferrous stop 26 may be formed from an unmagnetized ferromagnetic material, such as iron, cobalt or nickel or other ferrous material (e.g., steel, other alloys) or other ferromagnetic material known to a person skilled in the art having a high susceptibility to magnetization. Such ferromagnetic material is already magnetic on an atomic level—within a magnetic domain (group of atoms) the magnetization is uniform, however, the magnetic domains are not aligned with each other. An externally imposed magnetic field applied to an unmagnetized ferromagnetic material can cause the magnetic domains in the material to line up with each other, and the ferromagnetic material is said to be magnetized. The magnetic field of the magnetized ferromagnetic material may be lost with time as the magnetic domains return to their original unaligned configuration, and this is therefore a temporary magnet.

Ferrous stop 26 biases magnet 22 away from connecting surface 28 when there is no connection. This reduces undesirable magnetic flux at the connection surface 28 when there is no connection.

As noted above, magnetic connector 20′ is generally identical in operation to magnetic connector 20, including ferrous stops 26 and 26′.

When magnetic connectors 20 and 20′ are proximate each other, attraction between the respective magnets 22 and 22′ in connectors 20 and 20′ overcomes the biasing of ferrous stops 26 and 26′ and magnets 22 and 22′ are drawn towards connection surfaces 28 and 28′, respectively. As shown in FIG. 2, the north pole of magnet 22 aligns with a south pole of magnet 22′ and the magnet fields of magnets 22 and 22′ attract. This establishes a mechanical connection between devices 14 and 14′. An electrical connection may also be established through movement of magnets 22 and 22′, whether due to electrical signals passing through magnets 22 and 22′, or the movement of magnets 22 and 22′ otherwise establishing an electrical signal path. For example, in some embodiments, once magnets 22 and 22′ are engaged, an electrical connection may be formed through contacts disposed on surfaces 16 and 16′, the contacts being in electrical communication with respective magnets. In another embodiment, magnets 22 and 22′ may protrude through respective surfaces 16 and 16′ such that magnets 22 and 22′ contact each other directly. In other embodiments, electrical connections may be formed through leads carried by magnets 22 and 22′, rather than magnets 22 and 22′ themselves.

Movement of magnets 22 and 22′ to establish mechanical and electrical connections is described in detail in the WO 2015/070321 publication and U.S. Pat. No. 9,312,633.

Detection of connection between magnetic connectors 20 and 20′ (and hence devices 14 and 14′) or disconnection may be used to trigger behaviour changes of devices 14 and 14′. In one example, when devices 14 and 14′ cooperate to form a stitched display, devices 14 and 14′ can be configured to begin displaying content cooperatively when a connection is detected, or conversely, to end displaying content cooperatively when a disconnection is detected.

In another example, a device 14 can switch between drawing power from a connected device 14′, or drawing power from its internal battery upon detecting a connection or disconnection, respectively.

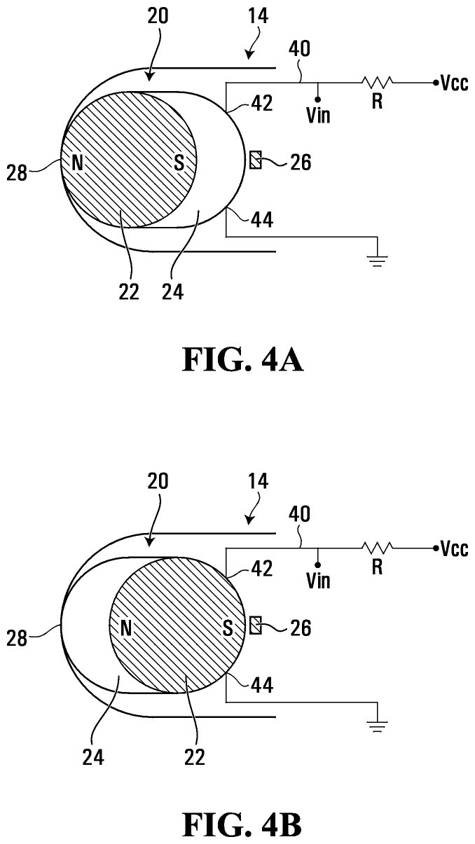

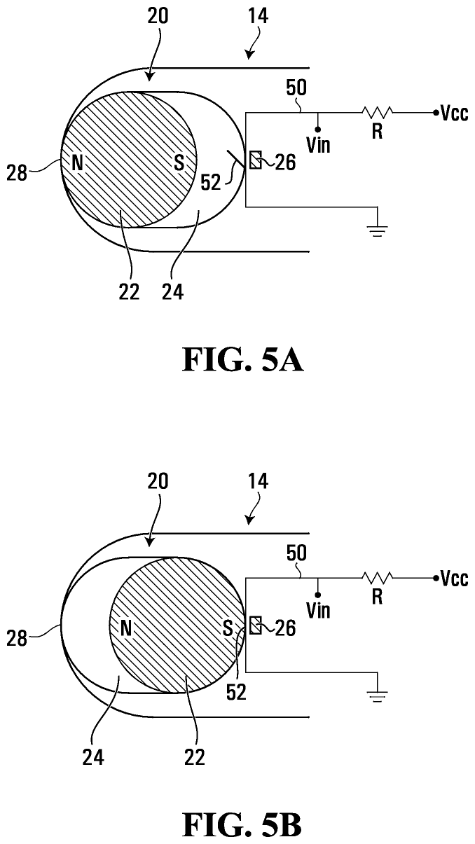

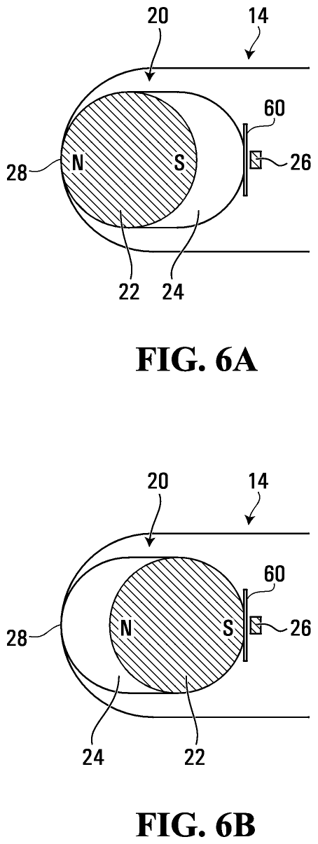

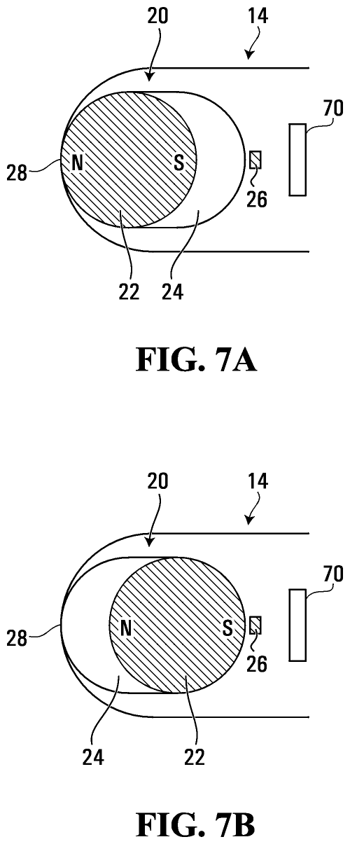

Detecting whether a magnetic connector 20 is in a connected state—e.g. connected to connector 20′ in device 14′—or not can be achieved in a number of ways. In a first embodiment, a detection circuit 40 is used to detect the position of magnet 22 in magnetic connector 20, is illustrated in FIGS. 4A and 4B. A second embodiment, using an alternative detection circuit 50, is illustrated in FIGS. 5A and 5B. A third embodiment, using a force sensor 60 to detect the position of magnet 22 in magnetic connector 20, is illustrated in FIGS. 6A and 6B. A fourth embodiment, using a Hall-effect sensor 70 to detect the position of magnet 22 in magnetic connector 20, is illustrated in FIGS. 7A and 7B. Each of these embodiments is discussed in further detail below.

FIG. 4A is a partial cross-section view of a magnetic connector 20, connected to a magnetic connector 20′ (not shown), and a detection circuit 40, exemplary of an embodiment. FIG. 4B is a partial cross-section view of magnetic connector 20 and detection circuit 40 of FIG. 4A, magnetic connector 20 disconnected from magnetic connector 20′ (not shown).

Detection circuit 40 is an electrical circuit and includes a first contact 42 and a second contact 44 that are received within cavity 24. Detection circuit 40 may be idealized as shown in FIGS. 4A and 4B, with a source voltage Vcc, a resistance R, a contact point Vin, and ground, represented symbolically. “Ground” is used to illustrate a common return path for current in detection circuit 40, and may be embodied, for example, as a conductor attached to one side of a power supply providing source voltage Vcc.

As shown in FIG. 4A, when magnetic connector 20 is connected to another magnetic connector, for example, connector 20′ (not shown), magnet 22 in connector 20 is magnetically attracted to magnet 22′ in magnetic connector 20′, and magnet 22 moves to connection surface 28 and into a first position in cavity 24. As a result, in this configuration there is no current path between first contact 42 and second contact 44—detection circuit 40 is open. Consequently, voltage at contact point Vin is high, and may be approximately equal to Vcc.

As shown in FIG. 4B, when magnetic connector 20 is not connected to another magnetic connector, for example, connector 20′ (not shown), magnet 22 is biased by the magnetic field of ferrous stop 26 which attracts magnet 22 to move magnet 22 away from connection surface 28 and into a second position in cavity 24. In second position, magnet 22 electrically connects first contact 42 and second contact 44, such that current flows from first contact 42 to second contact 44 through magnet 22, and detection circuit 40 is closed. Consequently, even with voltage applied at Vcc, voltage at Vin will be low, approximately equal to zero volts.

By, for example, determining the voltage level at Vin, detection circuit 40 may detect when magnet 22 is in second position, and hence disconnected from magnetic connector 20′.

In some embodiments, detection of whether detection circuit 40 is open or closed may be achieved using other techniques known to a person skilled in the art, for example, by measuring a voltage drop across R, or voltage or current at various points in detection circuit 40.

FIG. 5A is a partial cross-section view of a magnetic connector 20 connected to another magnetic connector, for example, connector 20′ (not shown), and a detection circuit 50, exemplary of an embodiment. FIG. 5B is a partial cross-section view of the magnetic connector 20 and detection circuit 50 of FIG. 5A, the magnetic connector disconnected from another magnetic connector, for example, connector 20′ (not shown).

Detection circuit 50 is an electrical circuit and includes a switch 52 that is received within cavity 24. Switch 52 may be a push button, or another mechanical actuator that responds to movement of magnet 22.

Detection circuit 50 may be idealized as shown in FIGS. 5A and 5B, with a source voltage Vcc, a resistance R, contact point Vin, and ground.

As shown in FIG. 5A, when magnetic connector 20 is connected, magnet 22 in magnetic connector 20 is magnetically attracted to magnet 22′ in connector 20′, and magnet 22 moves to connection surface 28 to a first position in cavity 24, and a switch 52 is open. Consequently, the voltage at Vin is high, and may be approximately equal to the voltage applied at source voltage Vcc.

As shown in FIG. 5B, if magnetic connector 20 is disconnected from connector 20′ (not shown), magnet 22 is biased by the magnetic field of ferrous stop 26 which attracts magnet 22 to move magnet 22 away from connection surface 28 and into a second position in cavity 24, and magnet 22 pushes switch 52 closed. As a result, current flows from Vcc through switch 52, since circuit 50 is closed. Consequently, the voltage at Vin is low, approximately zero volts.

By, for example, determining the voltage level at Vin, detection circuit 50 may detect when magnet 22 is in second position, and hence disconnected from connector 20′.

In some embodiments, detection of whether detection circuit 50 is open or closed may be achieved using techniques known to a person skilled in the art, for example, by measuring a voltage drop across R, or voltage or current at various points in detection circuit 40.

In comparison with detection circuit 40, detection circuit 50 differs at least in that magnet 22 does not form part of the closed circuit in second position.

FIG. 6A is a partial cross-section view of a magnetic connector 20 connected to another magnetic connector, for example, connector 20′ (not shown), and a force sensor 60, exemplary of an embodiment. FIG. 6B is a partial cross-section view of the magnetic connector 20 and force sensor 60 of FIG. 6A, the magnetic connector 20 disconnected from another magnetic connector, for example, connector 20′ (not shown).

As shown in FIG. 6A, magnet 22 exerts no force on force sensor 60 if magnetic connector 20 is connected to connector 20′ (not shown) in a first position.

As shown in FIG. 6B, if magnetic connector 20 is disconnected from connector 20′ (not shown), magnet 22 is biased by the magnetic field of ferrous stop 26 which attracts magnet 22 to move magnet 22 away from connection surface 28 and into a second position in cavity 24. In the second position, magnet 22 exerts force on force sensor 60.

A force sensor 60 may be, for example, a piezo-resistive force sensor, such as model FLX-A101-A marketed by Tekscan™ or similar, or a piezo-electric force sensor. Force sensor 60 may be sensitive to approximately 1 newton (N) or less.

By determining the force applied to force sensor 60, force sensor 60 may detect if magnet 22 is in the second position within cavity 24, and therefore magnetic connector 20 is not connected to connector 20′.

FIG. 7A is a partial cross-section view of a magnetic connector 20 connected to another magnetic connector, for example, connector 20′ (not shown), and a Hall-effect sensor 70, exemplary of an embodiment. FIG. 7B is a partial cross-section view of the magnetic connector 20 and Hall-effect sensor 70 of FIG. 7A, the magnetic connector 20 disconnected from another magnetic connector, for example, connector 20′ (not shown).

As shown in FIG. 7A, Hall-effect sensor 70, can be used to sense a decrease in magnetic flux density when magnetic connector 20 is connected to connector 20′ (not shown) and magnet 22 in magnetic connector 20 is magnetically attracted to magnet 22′ in magnetic connector 20′, and magnet 22 moves toward connection surface 28 (and away from Hall-effect sensor 70).

As shown in FIG. 7B, if magnetic connector 20 is disconnected from connector 20′ (not shown), magnet 22 is biased by the magnetic field of ferrous stop 26 which attracts magnet 22 to move magnet 22 away from connection surface 28 and into a second position in cavity 24, resulting in an increase in magnetic flux density on Hall-effect sensor 70.

Hall-effect sensor 70 operates by varying its output voltage in response to a magnetic flux density. By using Hall-effect sensor 70 to measure magnetic flux density exerted by magnet 22, Hall-effect sensor 70 may detect if magnet 22 is in the second position within cavity 24, and therefore magnetic connector 20 is not connected to connector 20′.

In the embodiments described above and illustrated in FIGS. 4A and 4B, 5A and 5B, 6A and 6B, and 7A and 7B, detecting whether magnetic connector 20 is in a connected state—e.g. connected to connector 20′ in device 14′—or not may be achieved by detecting the position of magnet 22 biased by ferrous stop 26 away from connection surface 28 in a second position in cavity 24, and as such, magnetic connector 20 is disconnected from magnetic connector 20′.

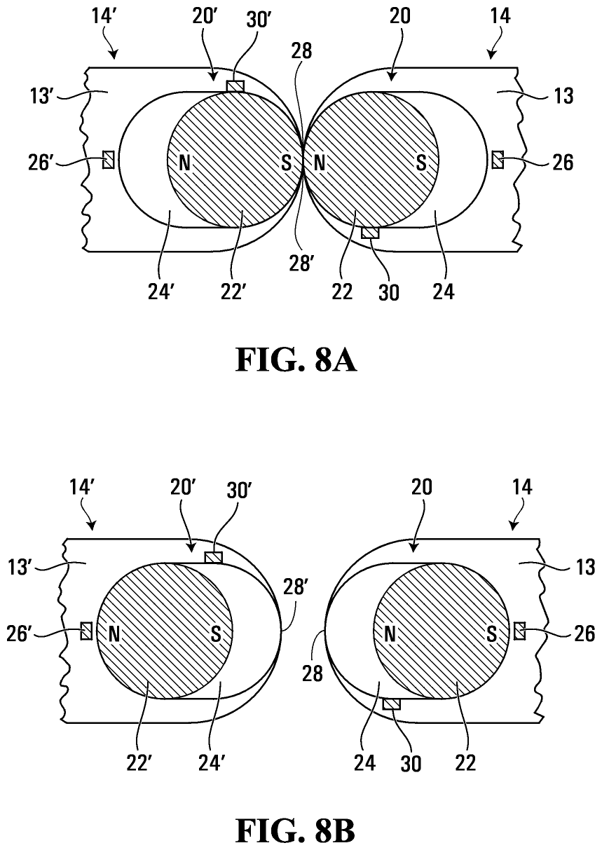

In some embodiments, detecting whether a magnetic connector 20 is in a connected state—e.g. connected to connector 20′ in device 14′—or not may be achieved by detecting the position of magnet 22 in a first position in cavity 24 at connection surface 28, for example, when attracted by magnet 22′ of connector 20′ as shown in FIG. 2 (detecting components not shown). In such embodiments, the detecting components described above with reference to FIGS. 4A and 4B, 5A and 5B, 6A and 6B, and 7A and 7B are positioned in device 14 to detect the position of magnet 22 in a first position in cavity 24 at connection surface 28. With magnet 22 positioned at connection surface 28, magnetic connector 20 may be connected to magnetic connector 20′. An embodiment in which a piezoelectric transducer 30 is used to detect the position of magnet 22 in a first position in cavity 24 at connection surface 28 in magnetic connector 20 and connected to connector 20′ is illustrated in FIGS. 8A and 8B.

FIG. 8A is a partial cross-section view of a magnetic connector 20 and a piezoelectric transducer 30 connected to another connector 20′ and another piezoelectric transducer 30′, exemplary of an embodiment. FIG. 8B is a partial cross-section view of magnetic connectors 20 and 20′ and piezoelectric transducers 30 and 30′ of FIG. 8A, magnetic connector 20 disconnected.

As shown in FIGS. 8A and 8B, piezoelectric transducer 30 is disposed in (or in some embodiments, adjacent to) cavity 24 of connector 20 such that it is not touching magnet 22 when the it is at the rear of cavity 24, but is touching magnet 22 when magnet 22 is drawn forward in cavity 24 into a first position at connection surface 28 (e.g., when attracted by magnet 22′ of connector 20′ as shown in FIG. 8A).

Piezoelectric transducer 30 can act as a sensor, to sense a vibration signal, and an actuator, to generate a vibration signal. Piezoelectric transducer 30′ of device 14′ is generally identical in structure and components to piezoelectric transducer 30 of device 14.

A connection between connectors 20 and 20′ may be detected when magnets 22 and 22′ move to form a vibration signal path between piezoelectric transducers 30 and 30′ in devices 14 and 14′. Piezoelectric transducer 30′ may generate a vibration signal that is an ultrasonic signal, or a signal in a lower frequency range. An example of a suitable piezoelectric transducers 30 and 30′ is Measurement Specialties™ LDT0 Solid State Switch/Vibration Sensor.

As shown in FIG. 8A, when connectors 20 and 20′ are connected, a vibration signal path is established between transducers 30 and 30′. The vibration signal path can extend through housings 13 and 13′ and connection surfaces 28 and 28′ of the devices 14 and 14′.

A vibration signal sent by transducer 30′ may be detected at transducer 30, and used by device 14 to determine that connector 20 is in a connected state. Similarly, a vibration signal sent by transducer 30 may be detected at transducer 30′, and used by device 14′ to determine that connector 20′ is in a connected state.

In another embodiment, transducers 30 and 30′ can be replaced by an electrical signal source, and an electrical signal path is established through magnets 24 and 24′ when the connectors 20 and 20′ are connected. Detection of an electrical signal, with reference to a common ground established between the contact of housings 13 and 13′, is used to determine that connectors 20 and 20′ are connected.

In some embodiments, a magnetic connector 20 of device 14 of FIGS. 1-3 may be connected and disconnected from a magnetic surface instead of device 14′. A magnetic surface may be part of, for example, a fridge, a vehicle dashboard, or other item where it may be useful to detect a magnetic connection.

When magnetic connector 20 is proximate a magnetic surface, attraction between magnet 22 and the magnetic surface may overcome the biasing of ferrous stop 26 and magnet 22 is drawn towards connection surface 28.

Detection of a magnetic connection or disconnection between magnetic connector 20 and the magnetic surface may be achieved using the same techniques as described above with reference to FIGS. 4A and 4B, 5A and 5B, 6A and 6B, 7A and 7B, and 8A and 8B.

In the embodiments shown above, cavity 24 in magnetic connector 20 is shaped to define a straight movement path for magnet 22. However, magnet 22 can be provided with more freedom of movement, and the connection and detection techniques described above may still apply.

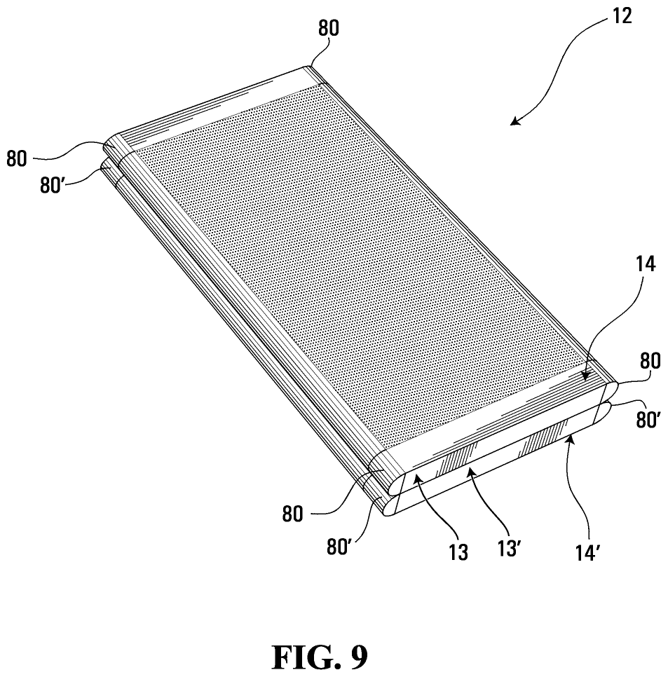

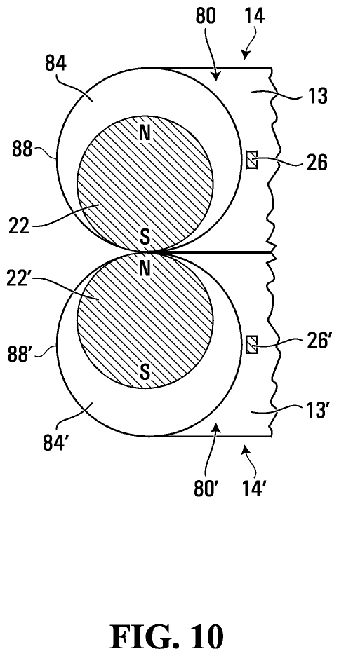

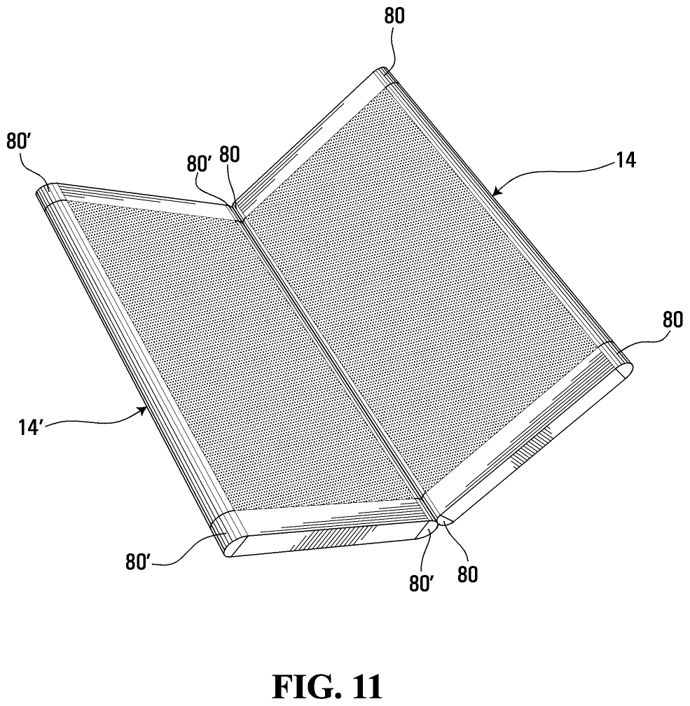

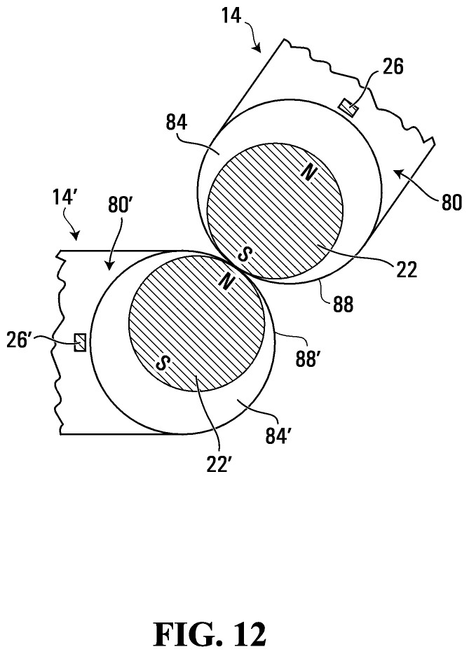

For example, in some embodiments, as illustrated in FIGS. 9-12, magnetic connectors 80 and 80′ may form a hinge around which devices 14 and 14′ can pivot relative to one another along their lateral edges 18 and 18′ when coupled, allowing switching from one of the configurations shown in FIGS. 9 and 11 to another, without interrupting the connection (mechanical or electrical). FIG. 10 and FIG. 12 each illustrate the internal components of magnetic connector 80, including magnet 22 in a cavity 84 with a circular cross-section, allowing magnets 22 and 22′ in connectors 80 and 80′ to form and maintain a connection as devices 14 and 14′ pivot relative to one another.

FIG. 9 is a perspective view of two electronic devices 14 and 14′, including magnetic connectors 80 and 80′, in a configuration, exemplary of an embodiment. FIG. 10 is a partial cross-section view of two connected magnetic connectors 80 and 80′ of the electronic devices 14 and 14′ of FIG. 9.

As shown in FIG. 9, devices 14 and 14′ may be arranged in a stacked configuration. Device 14 includes magnetic connectors 80 at each corner of their respective housings 13. Magnetic connectors 80′ of device 14′ are generally identical to connectors 80 of device 14.

Magnetic connector 80 is an alternative embodiment of connector 20 in which magnet 22 is within a cavity 84 that is circular in cross-section instead of rounded rectangle as with cavity 24. FIG. 10 shows the position of magnets 22 and 22′ in magnetic connectors 80 and 80′ given the pivot position of devices 14 and 14′ shown in FIG. 9. In a similar manner to the operation of connector 20, in connector 80 a magnetic stop, for example a ferrous stop 26, may draw magnet 22 to the rear of cavity 84 when there is no connection between magnetic connector 80 and magnetic connector 80′. When magnetic connectors 80 and 80′ are proximate each other, attraction between the respective magnets 22 and 22′ in the connectors 80 and 80′ overcomes the biasing of ferrous stops 26 and 26′ and magnets 22 and 22′ are drawn towards connection surfaces 88 and 88′, respectively. This establishes a connection between device 14 and device 14′, so that devices 14 and 14′ may be used together. Connection surfaces 88 and 88′ may each encompass a 180 degree semicircle through which a connection may be established.

FIG. 11 is a perspective view of electronic devices 14 and 14′ of FIG. 9 in an alternate configuration. FIG. 12 is a partial cross-section view of magnetic connector 80 of electronic device 14 connected to magnetic connector 80′ of electronic device 14′, of FIG. 11, illustrating the position of magnets 22 and 22′ in magnetic connectors 80 and 80′ given the pivot position of devices 14 and 14′ shown in FIG. 11.

Other embodiments are possible for biasing a magnet in a magnetic connector away from a connection surface, e.g., using other magnets, springs, etc., in lieu of ferrous stop 26.

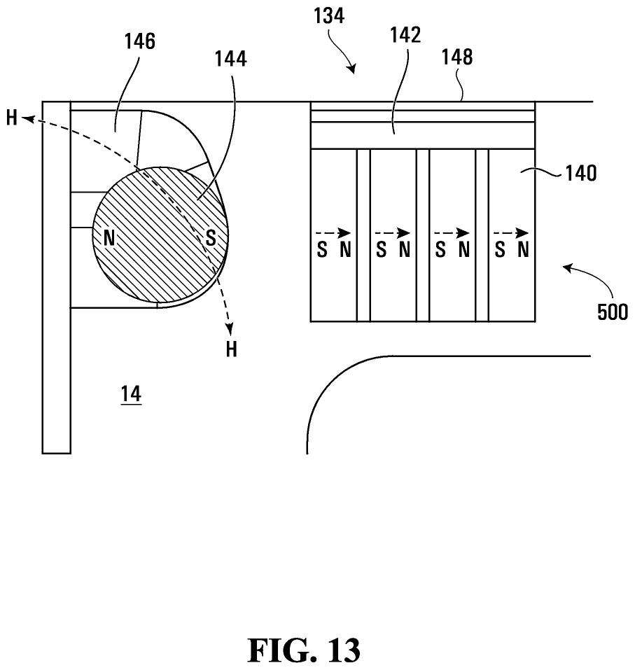

For example, FIG. 13 is a front cross-sectional view of a magnetic connector 500 in an electronic device 14, exemplary of an embodiment. FIG. 13 illustrates connector 500 disconnected from another connector. Connector 500 includes a plurality of core magnets 140 slidably received in a channel 142. Core magnets 140 may be formed of cylindrical disk magnets, as shown in FIG. 12, or other suitable types of magnets, such as a single cylindrical magnet.

Connector 500 further includes a side magnet 144. As shown in FIG. 13, side magnet 144 is spherical. Side magnet 144 is slidably and rotatably received in a channel 146. Channel 146 extends from the interior of housing of device 14 toward side, top, front and back edges of the housing to define a three-dimensional envelope within which side magnet 144 is movable. In particular, side magnet 144 is movable between a first position, shown in FIG. 13, in which side magnet 144 is withdrawn relative to each of the side, top, front and back surfaces of device 14; a second position in which side magnet 144 is extended toward a lateral surface of device 14 to switch connector 120 to an engaged state; and a third position in which side magnet 144 is extended toward a front or back surface of device 14 to switch connector 500 to an engaged state. Channel 146 defines a first path between the first and second positions, identified by the arrows marked H-H in FIG. 13, and a second path between the first and third positions (not shown).

As shown in FIG. 13, side magnet 144 and core magnets 140 may bias each other to a position away from a connection surface 148, and a ferrous stop can be omitted. The first position of side magnet 144, seen in FIG. 13, is the point in channel 146 closest to core magnets 140. Accordingly, in the absence of another connector, magnetic attraction between side magnet 144 and core magnets 140 biases side magnet 144 to the first position. Magnetic attraction likewise biases core magnets 140 to a withdrawn position within channel 142. Magnetic attraction between side magnet 144 and core magnets 140 may also cause side magnet 144 to rotate into alignment with core magnets 140. As depicted, the north-south alignment of core magnets 140 is parallel to the lateral surface of device 14. Accordingly, side magnet 144 is rotated so that its north-south poles are parallel to the lateral surface of device 14.

U.S. Pat. No. 9,312,633 describes various embodiments of a magnetic connector in which magnets are biased to a disconnected position by way of interaction between core magnets and side magnets, which move in their respective cavities.

The connection/disconnection detection techniques described above can be applied to movement of side magnet 124.

Of course, the above described embodiments are intended to be illustrative only and in no way limiting. The described embodiments are susceptible to many modifications of form, arrangement of parts, details and order of operation. The invention is intended to encompass all such modification within its scope, as defined by the claims.

What is claimed is:

1. A device magnetically interconnectable to another device, comprising:
a body defining a cavity;
a magnet received within said cavity, movable between a first position and a second position in said cavity, and magnetically interconnectable with an external magnet in said another device that urges said magnet to said first position;
a magnetic stop magnetically attracting said magnet toward said second position in said cavity; and
a sensor to detect said magnet in one of said first position and said second position.

2. The device of claim 1, further comprising:
a first contact and a second contact received within said cavity;
wherein said magnet electrically connects said first contact and said second contact in one of said first position and said second position.

3. The device of claim 1, further comprising:
a switch received within said cavity;
wherein said magnet mechanically actuates said switch to a closed position in one of said first position and said second position.

4. The device of claim 3, wherein said switch is a push button.

5. The device of claim 1, wherein
said sensor is a force sensor that detects a mechanical force exerted by said magnet.

6. The device of claim 1, wherein
said sensor is a Hall-effect sensor.

7. The device of claim 1, further comprising:
a piezo-electric transducer;
wherein said transducer detects a vibration signal transmitted from said another device to said magnet in said first position.

8. The device of claim 7, wherein said vibration signal is an ultrasonic signal.

9. The device of claim 1, further comprising:
a piezo-electric transducer;
wherein said transducer generates a vibration signal transmitted to said another device through said magnet in said first position.

10. The device of claim 1, wherein said magnet is electrically interconnectable with said external magnet.

11. The device of claim 1, wherein said magnetic stop is ferromagnetic.

12. The device of claim 1, wherein said magnetic stop is a permanent magnet.

13. A method of detecting a position of a magnet in a device magnetically interconnectable to another device, comprising:
biasing said magnet, received within a cavity defined by a body and magnetically interconnectable with an external magnet in said another device in a first position in said cavity, into a second position in said cavity; and
detecting said magnet in one of said first position and said second position.

14. The method of claim 13, further comprising:
electrically connecting, by said magnet in one of said first position and said second position, a first contact and a second contact received within said cavity.

15. The method of claim 13, further comprising:
closing, by said magnet in one of said first position and said second position, a switch received within said cavity.

16. The method of claim 13, further comprising:
exerting, by said magnet in one of said first position and said second position, a mechanical force on a force sensor.

17. The method of claim 13, further comprising:
exerting, by said magnet, a magnetic flux density on a Hall-effect sensor.

18. The method of claim 13, further comprising:
detecting a vibration signal transmitted from said another device to said magnet in said first position.

19. The method of claim 13, further comprising:
generating a vibration signal transmitted to said another device through said magnet in said first position.

20. The method of claim 13, further comprising:
detecting an electrical signal transmitted from said another device to said magnet in said first position.
